(19) United States
(12) Patent Application Publication
(10) Pub. No.: US 2012/0032288 A1
(43) Pub. Date: Feb. 9, 2012

(54) MAGNETORESISTIVE ELEMENT AND METHOD OF MANUFACTURING THE SAME

(75) Inventor: Kazuhiro TOMIOKA, Yokohama-shi (JP)

(73) Assignee: KABUSHIKI KAISHA TOSHIBA, Tokyo (JP)

(21) Appl. No.: 13/051,869

(22) Filed: Mar. 18, 2011

(30) Foreign Application Priority Data
Aug. 4, 2010 (JP) 2010-175605

(51) Int. Cl. H01L 29/82; H01L 21/8246

(52) U.S. Cl. 257/421; 438/3; 257/E21.665; 257/E29.323

(57) ABSTRACT

According to one embodiment, a magnetoresistive element comprises a multilayered structure and insulating film. The multilayered structure is formed on a substrate, and includes a fixed layer which has the invariable magnetization direction, a free layer which contains cobalt or iron and has the variable magnetization direction, and a nonmagnetic layer sandwiched between the fixed layer and free layer. The insulating film is formed on the side surface of the free layer, and contains boron and nitrogen.

### CROSS-REFERENCE TO RELATED APPLICATIONS

This application is based upon and claims the benefit of priority from Japanese Patent Application No. 2010-175605, filed Aug. 4, 2010; the entire contents of which are incorporated herein by reference.

### FIELD

Embodiments described herein relate generally to a magnetoresistive element and a method of manufacturing the same.

### BACKGROUND

A magnetic random access memory (MRAM) using a ferromagnetic material is currently viewed as a candidate for future nonvolatile memories offing high speed, large capacity, and low power consumption. An MRAM includes a magnetic tunnel junction (MTJ) element exploiting the tunneling magnetoresistive (TMR) effect as a memory element, and stores data based on the magnetization state of each MTJ element.

In a conventional MRAM in which data is written by the magnetic field of an interconnection current, the holding force increases when the size of the MTJ element decreases. This often increases the current required for writing. Accordingly, it is difficult for the conventional MRAM to simultaneously achieve a small cell size for large capacity and low current.

As a write method for solving this problem, a spin-transfer-type MRAM using the spin momentum transfer (SMT) write method has been proposed. In the spin-transfer-type MRAM, data is written by directly supplying a current to an MTJ element. That is, the magnetization direction of a free layer (recording layer) is changed by the direction of this current. Also, an MTJ element including two fixed layers arranged to sandwich a free layer can increase the spin torque. This makes it possible to reduce the critical current density of the MTJ element.

A ferromagnetic material is used as the free layer of the MTJ element. More specifically, a ferromagnetic material containing at least one of cobalt (Co) and iron (Fe) as elements is used as the free layer. Co and Fe have high characteristics as ferromagnetic materials and can form a high-performance MTJ element.

As an MTJ element patterning method, a dry etching method that uses, as a reaction gas, carbon monoxide (CO) to which a gaseous nitrogen-containing compound such as ammonia (NH₃) or an amine is added is available. Since the vapor pressure of this gaseous CO is low, however, the taper angle of the MTJ element decreases (to less than 70°) after the etching. This makes gaseous CO unsuited to processing high-density microdevices in gigabit-order.

Accordingly, when processing a fine MTJ element having a diameter of 100 nm or less by plasma etching in order to manufacture a highly integrated memory, a halogen such as chlorine (Cl₂) is used as an etching gas. When the side surface of the MTJ element is exposed, however, Co or Fe used as a magnetic material film accelerates corrosion by Cl₂ remaining by adsorption on the side surface, thereby forming a damage layer. This poses problems such as the decrease in signal amount of the MTJ element.

### BRIEF DESCRIPTION OF THE DRAWINGS

FIG. 1 is a sectional view showing the structure of an MTJ element in an MRAM according to an embodiment;

FIG. 2 is a view schematically showing a manufacturing apparatus for manufacturing the MTJ element in the MRAM according to the embodiment;

FIG. 3 is a sectional view showing a manufacturing step of the MTJ element in the MRAM according to the embodiment;

FIG. 4 is a sectional view showing a manufacturing step following FIG. 3 of the MTJ element in the MRAM according to the embodiment;

FIG. 5 is a sectional view showing a manufacturing step following FIG. 4 of the MTJ element in the MRAM according to the embodiment;

FIG. 6 is a sectional view showing a manufacturing step following FIG. 5 of the MTJ element in the MRAM according to the embodiment;

FIG. 7 is a sectional view showing a manufacturing step following FIG. 5 of the MTJ element in the MRAM according to the embodiment; and

FIGS. 8A and 8B are graphs showing the results of VSM measurements of the MTJ element in the MRAM according to the embodiment.

### DETAILED DESCRIPTION

In general, according to one embodiment, a magnetoresistive element comprises a multilayered structure and insulating film. The multilayered structure is formed on a substrate, and includes a fixed layer which has the invariable magnetization direction, a free layer which contains cobalt or iron and has the variable magnetization direction, and a nonmagnetic layer sandwiched between the fixed layer and free layer. The insulating film is formed on the side surface of the free layer, and contains boron and nitrogen.

This embodiment will be explained below with reference to the accompanying drawing. In the drawing, the same reference numbers denote the same parts.

### <Structure>

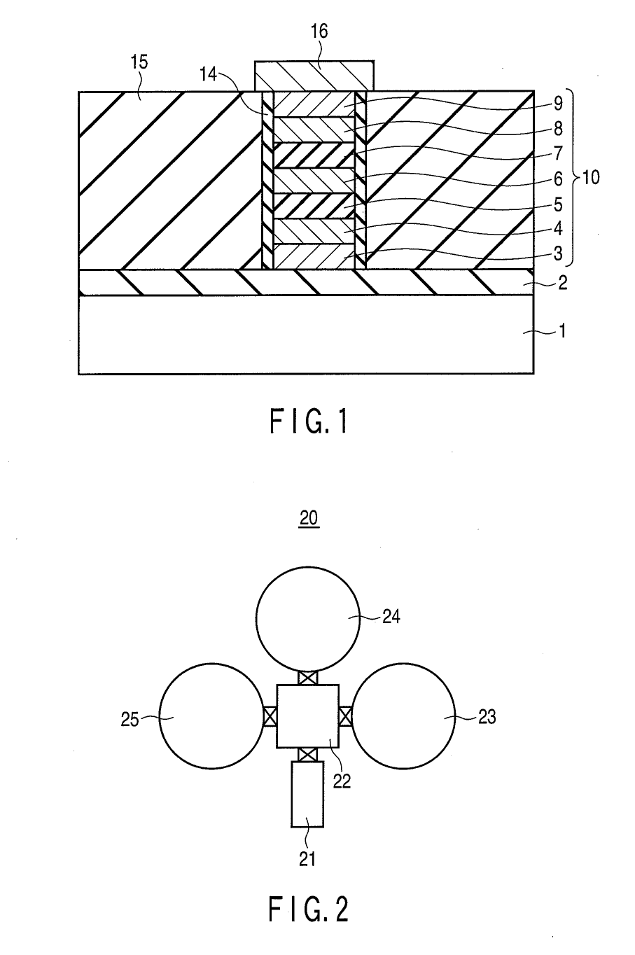

The structure of an MTJ element in an MRAM according to this embodiment will be explained with reference to FIG. 1. FIG. 1 is a sectional view showing the structure of the MTJ element of this embodiment.

As shown in FIG. 1, the MRAM according to this embodiment includes a semiconductor substrate 1, interlayer film 2, MTJ element 10, and interconnection layer 16. The interlayer film 2 is formed on the semiconductor substrate 1. An interconnection layer (not shown) is formed in the interlayer film 2. This interconnection layer is connected to a lower electrode 3 of the MTJ element 10. The MTJ element 10 is formed on the interlayer film 2. An interlayer dielectric film 15 is formed around the MTJ element 10. The interconnection layer 16 is formed on the MTJ element 10. The interconnection layer 16 is connected to an upper electrode 9 of the MTJ element 10. The interconnection layer in the interlayer film 2 and the interconnection layer 16 are used to bidirectionally supply a current to the MTJ element 10.

The MTJ element includes a multilayered structure including the lower electrode 3, a first fixed layer (pinned layer) 4, a first tunnel barrier layer (nonmagnetic layer) 5, a free layer (recording layer) 6, a second tunnel barrier layer (nonmagnetic layer) 7, a second fixed layer 8, and the upper electrode 9 sequentially formed on the interlayer film 2, and an insulating film 14 (referred to as a boron nitride [BN] film 14 hereinafter) containing nitrogen and boron and covering the side surface of the multilayered structure.

More specifically, in the multilayered structure of the MTJ element 10, the first fixed layer 4 is formed below the free layer 6 with the nonmagnetic layer 5 sandwiched between them, and the second fixed layer 8 is formed above the free layer 6 with the nonmagnetic layer 7 sandwiched between them. That is, the MTJ element 10 of this embodiment is an example of a magnetoresistive element having a so-called dual pinned layer structure (double junction structure). Note that the MTJ element 10 of this embodiment is not limited to the double junction structure, and may also have a single junction structure including a free layer, a fixed layer, and a nonmagnetic layer formed between them. The planar shape of the MTJ element 10 of this embodiment is, for example, a circle. However, the planar shape is not limited to a circle, and can also be a square, rectangle, ellipse, or the like.

In the first and second fixed layers 4 and 8, the direction of magnetization (or spin) is fixed (invariable). Also, the magnetization directions in the first and second fixed layers 4 and 8 are set antiparallel (in opposite directions).

The magnetization direction in the free layer 6 can be changed (reversed) (is variable). In each of the first fixed layer 4, second fixed layer 8, and free layer 6, the direction of easy magnetization can be perpendicular to or parallel to the film surface. That is, the MTJ element 10 can be formed by using either a perpendicular magnetization film or in-plane magnetization film.

Ferromagnetic materials are used as the first fixed layer 4, the second fixed layer 8 and the free layer 6. More specifically, a ferromagnetic material containing at least one element selected from, for example, cobalt (Co), iron (Fe), nickel (Ni), iridium (Ir), platinum (Pt), manganese (Mn), and ruthenium (Ru) is used as the first fixed layer 4 and the second fixed layer 8. A ferromagnetic material containing at least one element selected from, for example, cobalt (Co) and iron (Fe) is used as the free layer 6. It is also possible to add an element such as boron (B), carbon (C), or silicon (Si) to the ferromagnetic material in order to adjust the saturation magnetization or magnetocrystalline anisotropy.

Note that a synthetic antiferromagnetic (SAF) structure may be used as the first and second fixed layers 4 and 8. The SAF structure is a multilayered structure including a first magnetic layer/nonmagnetic layer/second magnetic layer in which the magnetization directions in the two magnetic layers are antiparallel with the nonmagnetic layer sandwiched between them. Since the SAF structure increases the magnetization fixing force in the first and second fixed layers 4 and 8, it is possible to improve the resistance and thermal stability against an external magnetic field.

A conductor such as Pt, Ir, or Ru is used as the lower electrode 3 and upper electrode 9.

A metal oxide such as magnesium oxide or aluminum oxide is used as the first tunnel barrier layer 5. A paramagnetic metal such as copper (Cu), gold (Au), or silver (Ag) is used as the second tunnel barrier layer 7. When using a metal oxide as the first tunnel barrier layer 5, the TMR effect is usable. When using a paramagnetic metal as the second tunnel barrier layer 7, the giant magnetoresistive (GMR) effect is usable. The MR ratio of the TMR effect is much higher than that of the GMR effect. Therefore, data is read by mainly using the MR ratio of the TMR effect.

Note that the stacking order may be reversed in the multilayered structure forming the MTJ element 10. In this case, a paramagnetic metal is used as the first tunnel barrier layer 5, and a metal oxide is used as the second tunnel barrier layer 7.

It is also possible to use a metal oxide as both the first tunnel barrier layer 5 and the second and tunnel barrier layer 7. In this case, the first tunnel barrier layer 5 and the second tunnel barrier layer 7 are set to have different film thicknesses in order to produce a difference between the MR ratios when reading data.

The BN film 14 is formed on the side surface of the multilayered structure of the MTJ element 10 according to this embodiment. The BN film 14 is formed on the entire circumferential surface of the multilayered structure and covers the side surface of the multilayered structure. Note that a BCN film further containing C may be formed instead of the BN film 14. When the multilayered structure is a circular (columnar) structure having a diameter of about 100 nm, the film thickness of the BN film 14 is, for example, 50 nm or less.

The MTJ element 10 of this embodiment is a spin-transfer-type magnetoresistive element. When writing to or reading from the MTJ element 10, therefore, a current is bidirectionally supplied to the MTJ element 10 in a direction perpendicular to the film surfaces (stacked surfaces).

More specifically, data is written to the MTJ element 10 as follows.

When supplying electrons from the first fixed layer 4 (i.e., electrons moving from the first fixed layer 4 toward the free layer 6), electrons spin-polarized in the same direction as the magnetization direction in the first fixed layer 4 and electrons reflected by the second fixed layer 8 and spin-polarized in the direction opposite to the magnetization direction in the second fixed layer 8 are injected into the free layer 6. In this state, the magnetization direction in the free layer 6 is matched with that in the first fixed layer 4. This makes the magnetization directions in the first fixed layer 4 and free layer 6 parallel to each other. In this parallel arrangement, the resistance of the MTJ element 10 is minimum. This state is defined as, for example, binary 0.

In contrast, when supplying electrons from the second fixed layer 8 (i.e., electrons moving from the second fixed layer 8 toward the free layer 6), electrons spin-polarized in the same direction as the magnetization direction in the second fixed layer 8 and electrons reflected by the first fixed layer 4 and spin-polarized in the direction opposite to the magnetization direction in the first fixed layer 4 are injected into the free layer 6. In this state, the magnetization direction in the free layer 6 is made opposite to that in the first fixed layer 4. This makes the magnetization directions in the first fixed layer 4 and free layer 6 antiparallel to each other. In this antiparallel arrangement, the resistance of the MTJ element 10 is maximum. This state is defined as, for example, binary 1.

Also, data is read as follows.

A read current is supplied to the MTJ element 10. This read current is set to have a magnitude (smaller than that of the write current) such that the magnetization direction in the free layer 6 does not reverse. A semiconductor device capable of a memory operation is obtained by detecting the change in resistance value of the MTJ element 10 in this state.

### <Manufacturing Apparatus>

A manufacturing apparatus for manufacturing the MTJ element in the MRAM according to this embodiment will be explained below with reference to FIG. 2. FIG. 2 is a schematic view of the manufacturing apparatus for manufacturing the MTJ element of this embodiment.

As shown in FIG. 2, a manufacturing apparatus 20 for manufacturing the MTJ element of this embodiment includes a substrate loading chamber 21, substrate transport chamber 22, first plasma processing chamber 23, hydrogen processing chamber 24, and second plasma processing chamber 25.

In the manufacturing apparatus 20, the substrate loading chamber 21, first plasma processing chamber 23, hydrogen processing chamber 24, and second plasma processing chamber 25 are arranged around the substrate transport chamber 22 with a vacuum valve interposed between each chamber and the substrate transport chamber 22. In the manufacturing apparatus 20, therefore, a substrate (wafer) is transported in a vacuum between these chambers. Accordingly, the substrate surface is not contaminated with the atmosphere and the like, but kept clean.

In the manufacture of the MTJ element, a substrate is first installed in the substrate loading chamber 21. Then, the substrate is loaded into the substrate transport chamber 22 after the substrate loading chamber 21 is sufficiently exhausted to a predetermined ultimate pressure, so as not to mix any external air in the manufacturing apparatus 20. After that, in deposition and etching steps, the substrate is transported to the first plasma processing chamber 23 or the second plasma processing chamber 25. Also, in a chlorine (Cl₂) removal step (described later), the substrate is transported to the hydrogen processing chamber 24. The hydrogen processing chamber 24 can supply hydrogen radicals by plasma excitation by using microwaves.

Note that in the above-mentioned vacuum transport system (manufacturing apparatus 20), the degree of vacuum is of the order of 10⁻⁹ Torr, values in the range of 0.5×10⁻⁸ to 1×10⁻⁹ Torr being allowable. More specifically, the ultimate degree of vacuum of the substrate transport chamber 22 is of the order of 10⁻⁹ Torr.

### <Manufacturing Method>

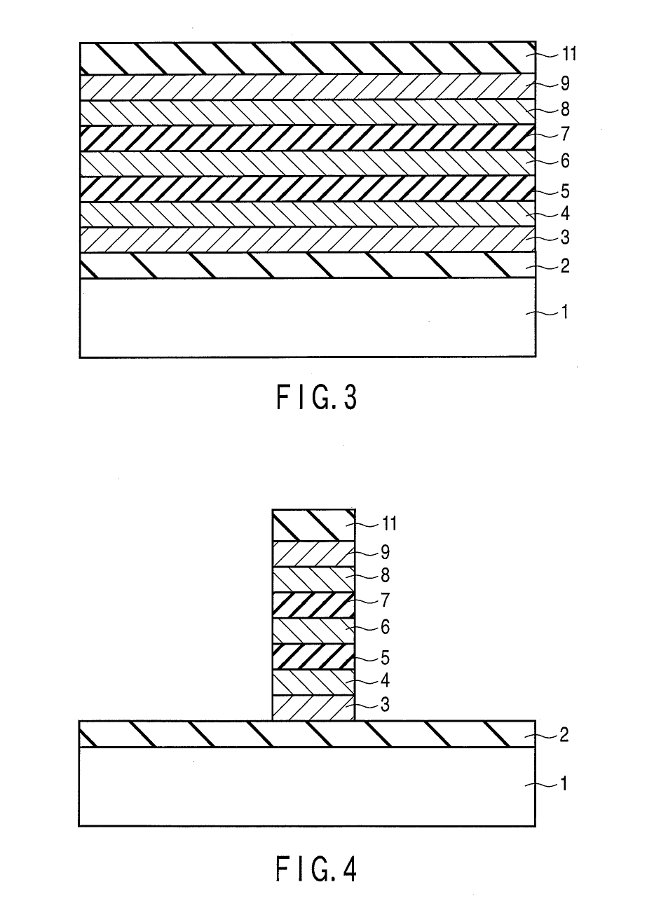

A method of manufacturing the MTJ element in the MRAM according to this embodiment will be explained below with reference to FIGS. 3, 4, 5, 6, and 7. FIGS. 3, 4, 5, 6, and 7 are sectional views showing the manufacturing steps of the MTJ element of this embodiment.

First, as shown in FIG. 3, a multilayered structure as the MTJ element 10 is formed on the entire wafer surface. More specifically, after an interlayer film 2 is formed on a semiconductor substrate 1, a multilayered structure is formed by sequentially stacking a lower electrode 3, first fixed layer 4, first tunnel barrier layer 5, free layer 6, second tunnel barrier layer 7, second fixed layer 8, and upper electrode 9 on the interlayer film 2. This multilayered structure is formed by, for example, sputtering.

Then, a silicon oxide film 11 as a hard mask is formed on the multilayered structure. The silicon oxide film 11 is formed by, for example, CVD. After that, a photoresist (not shown) having a pattern to be processed is formed on the silicon oxide film 11 by photolithography.

Subsequently, as shown in FIG. 4, the silicon oxide film 11 is patterned by, for example, plasma etching by using the photoresist as a mask. This plasma etching uses a fluorocarbon containing, for example, CF₄, CHF₃, C₄F₈, or C₄F₆ as an etching gas.

The multilayered structure as the MTJ element 10 is then patterned by, for example, plasma etching by using the silicon oxide film 11 as a hard mask. This exposes the side surface (circumferential surface) of the multilayered structure. This plasma etching is performed in the first plasma processing chamber 23 shown in FIG. 2.

More specifically, the wafer is transported to the first plasma processing chamber 23, and Cl₂ is supplied as an etching gas at a flow rate of 200 SCCM. The internal pressure of the first plasma processing chamber 23 is set at 1 Pa. Also, electric power to be applied to an upper coil (not shown) installed in the first plasma processing chamber 23 is set at 1,000 W, and bias power is set at 400 W. A 13.56-MHz radio-frequency (RF) drive for plasma excitation is applied to the upper coil, while a 2-MHz RF drive is applied to an electrode on which the wafer is placed in order to draw ions from the plasma.

Note that the etching gas is not limited to Cl₂, and it is possible to similarly use a halogen compound such as HCl or BCl₃. Furthermore, an inert gas such as Ar, He, or Xe or a gas containing a slight amount of an oxidizing or nitriding material such as O₂ or N₂ may be added to Cl₂, HCl, or BCl₃. It is also possible to add not only an inert gas or a gas containing an oxidizing or nitriding material, but also various other kinds of gases in order to obtain a target processed shape. The internal pressure of the first plasma processing chamber 23 is not limited to 1 Pa, but need only be 0.5 to 3 Pa or, more desirably, 1 to 2 Pa. The upper coil power is not limited to 1,000 W, but need only be 200 to 4,000 W or, more desirably, 500 to 1,500 W. The bias power is not limited to 400 W, but need only be 300 to 600 W or, more desirably, 300 to 400 W.

After the wafer on which the multilayered structure as the MTJ element 10 is formed is thus placed on the electrode in the first plasma processing chamber 23, etching is performed for 2 minutes by plasma excitation, thereby patterning the multilayered structure.

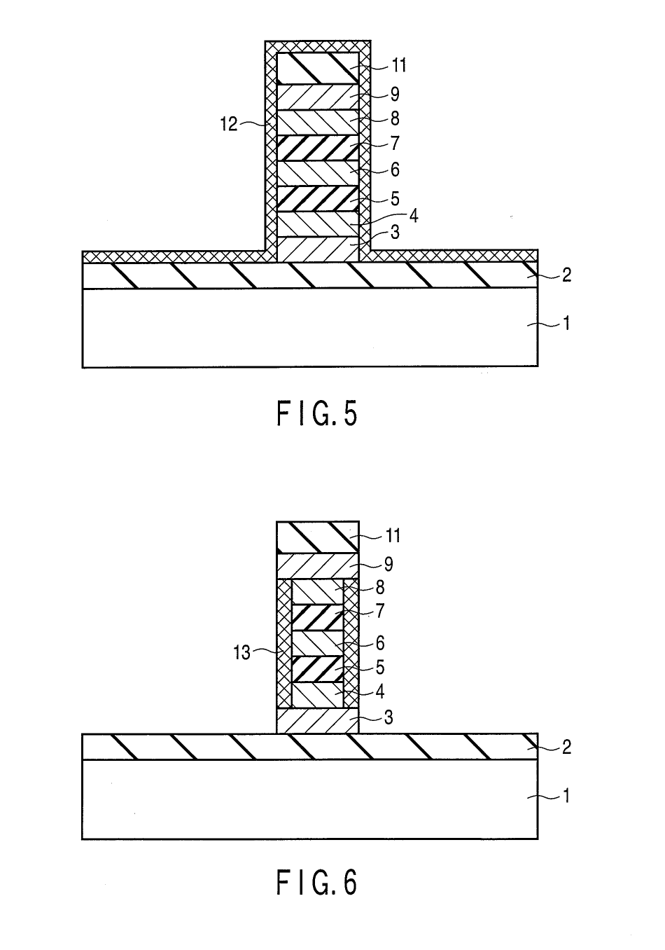

In this step, as shown in FIG. 5, Cl₂ 12 used as an etching gas remains on the entire surface of the patterned multilayered structure. That is, on the side surface of the multilayered structure, Cl₂ 12 is adsorbed to Co or Fe used as the first fixed layer 4, the second fixed layer 8 and the free layer 6.

When moving the wafer between the chambers, for example, the Cl₂ 12 adsorbed to the side surface reacts with water (particularly, H ions) in the atmosphere, and generates HCl (hydrogen chloride). Also, the HCl dissolves in water in the atmosphere to form hydrochloric acid, thereby generating H ions and Cl ions. The Cl ions react with Co or Fe used in the first fixed layer 4, the second fixed layer 8 and the free layer 6. That is, corrosion continuously advances on the side surface of the multilayered structure due to the pitting corrosion effect of the Cl ions. As shown in FIG. 6, this forms a damage layer 13 made of cobalt chloride (CoCl₂) or iron chloride (FeCl₂) as the corrosion product on the side surface of the multilayered structure. The damage layer 13 is formed to have a film thickness of a few nanometers to a few tens of nanometers. The damage layer 13 poses a serious problem in the operation of the MTJ element. For example, a leakage current is produced between the magnetic layers (between the first fixed layer 4, second fixed layer 8, and free layer 6), the magnetization characteristic of the free layer 6 deteriorates, or film peels after an interlayer dielectric film 15 is formed.

To solve this problem, this embodiment performs the following steps after the multilayered structure is patterned.

First, the Cl₂ 12 adhering to the side surface of the multilayered structure is removed. This removal of the Cl₂ 12 is performed in the hydrogen processing chamber 24 shown in FIG. 2.

More specifically, the wafer is transported from the first plasma processing chamber 23 to the hydrogen processing chamber 24. Since the wafer is transported by the vacuum transport system, the Cl₂ 12 adhering to the side surface of the multilayered structure is not exposed to the atmosphere. That is, it is possible to prevent the Cl₂ 12 from reacting with the water in the atmosphere and changing into hydrochloric acid.

After that, hydrogen (H₂) is supplied at a flow rate of 500 SCCM to the hydrogen processing chamber 24. The internal pressure of the hydrogen processing chamber 24 is set at 100 Pa. To perform plasma excitation, a microwave having a frequency of 2.45 GHz is applied at 1,500 W. Also, a plate on which the wafer is placed is heated to 250° C. Consequently, a remote plasma excited by the microwave supplies active hydrogen. This hydrogen plasma (hydrogen radicals) makes it possible to remove and reduce the residual Cl₂ 12. Processing by this remote plasma is performed for 10 minutes.

The reaction between the hydrogen plasma and Cl₂ 12 occurs as follows. The Cl₂ 12 reacts with the supplied hydrogen plasma and changes into HCl. This reaction occurs at a high temperature and low pressure in the hydrogen processing chamber 24. Therefore, HCl is not exposed to the water in the atmosphere. That is, Cl does not react with the multilayered structure. This makes it possible to directly vaporize the generated HCl, and remove the residual Cl₂ 12.

Note that the gas for removing the Cl₂ 12 is not limited to H₂, and it is possible to similarly use an inert gas such as nitrogen (N₂) or argon (Ar).

Also, the internal pressure of the hydrogen processing chamber 24 is not limited to 100 Pa, but need only be 10 to 200 Pa or, more desirably, 50 to 100, Pa. The microwave is not limited to 1,500 W, but need only be 500 to 3,000 W or, more desirably, 1,000 to 2,000 W.

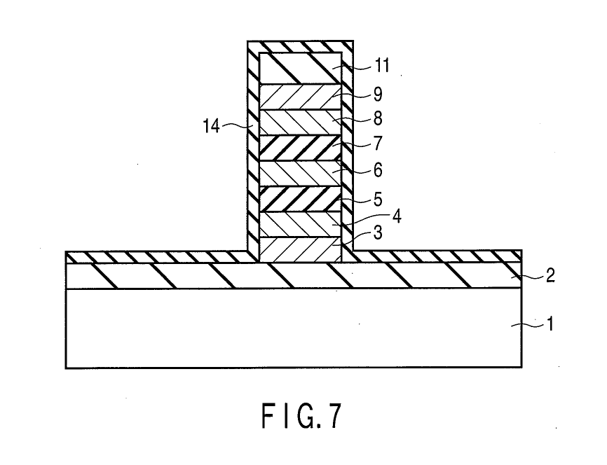

Subsequently, as shown in FIG. 7, a BN film 14 is formed on the entire surface of the multilayered structure from which the Cl₂ 12 is removed. In this step, the BN film 14 need only be formed on the side surfaces of at least the first fixed layer 4, the second fixed layer 8 and the free layer 6 of the multilayered structure. This formation of the BN film 14 is performed in the first plasma processing chamber 23 shown in FIG. 2. That is, the BN film 14 is formed in the same chamber as that for the plasma etching of the multilayered structure.

More specifically, the wafer is transported from the hydrogen processing chamber 24 to the first plasma processing chamber 23. In this step, the wafer is transported by the vacuum transport system.

After that, boron trichloride (BCl₃) and N₂ are respectively supplied at a flow rate of 50 SCCM to the first plasma processing chamber 23. The internal pressure of the first plasma processing chamber 23 is set at 2 Pa. Also, the electric power to be applied to the upper coil is set at 1,000 W, and the bias power is set at 100 W. Thus, gaseous BCl₃ and N₂ are formed into a plasma.

In this step, the deposition rate of the BN film 14 is about 60 nm/min on the upper surfaces (of the silicon oxide film 11 and interlayer film 2), and about 20 nm/min on the side surface (of the multilayered structure). That is, the BN film 14 having a film thickness of about 50 nm can be deposited on the side surface of the multilayered structure by performing discharge for 2½ minutes.

Note that the gas for forming the BN film 14 need only be a mixture of BCl₃ and N₂, and the flow rate ratio need only be BCl₃/N₂=95/5 to 10/90. It is also possible to add a gas such as methane (CH₃) or carbon monoxide (CO) to the mixture of BCl₃ and N₂. In this case, a BCN film is formed instead of the BN film 14.

Furthermore, the internal pressure of the first plasma processing chamber 23 is not limited to 2 Pa, but need only be 0.5 to 200 Pa or, more desirably, 1 to 20 Pa. The upper coil power is not limited to 1,000 W, but need only be 200 to 4,000 W or, more desirably, 500 to 2,000 W. The bias power is not limited to 100 W, but need only be 200 W or less or, more desirably, 5 to 100 W.

As the source gas, boron trifluoride (BF₃) or diborane (B₂H₆) may also be used instead of BCl₃. In this case, the conditions such as the flow rate, pressure, upper coil power, and bias power can be the same as those for BCl₃.

Then, a step of removing a slight amount of Cl₂ adhering to the side surface of the BN film 14 may be performed. In this step, the wafer is transported from the first plasma processing chamber 23 to the hydrogen processing chamber 24, and the Cl₂ is removed in the same manner as in the above-described method of removing the Cl₂ 12.

Subsequently, as shown in FIG. 1, the BN film 14 and silicon oxide film 11 are removed from the upper surface. After that, an interlayer dielectric film 15 is formed on the interlayer film 2 and around the MTJ element 10, and an interconnection layer 16 is formed on the MTJ element 10.

### <Vibrating Sample Magnetometer (VSM) Measurement>

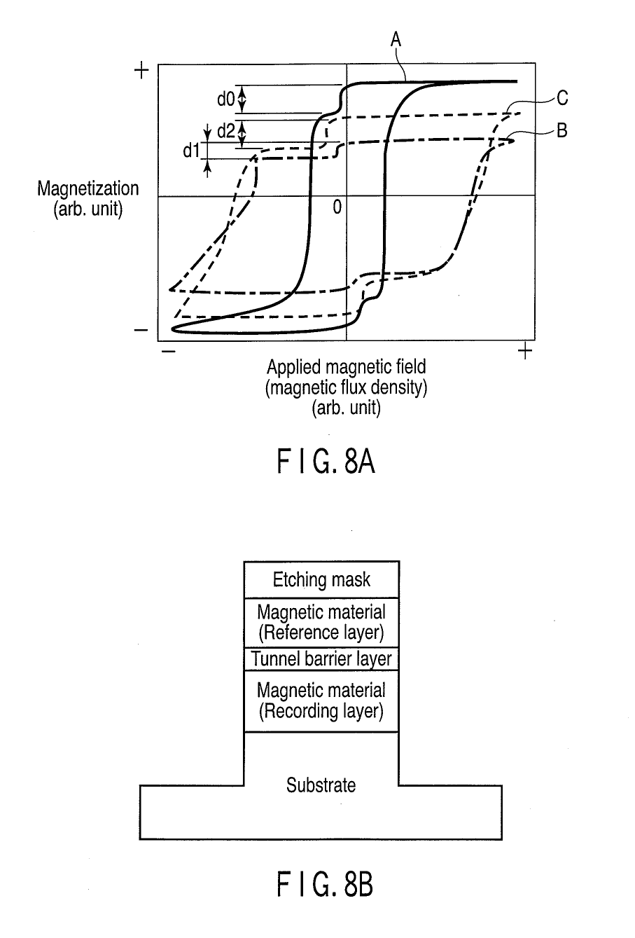

FIG. 8A shows the relationship between the applied magnetic flux density and magnetization when VSM measurement was performed on samples of the MTJ element shown in FIG. 8B. Referring to FIG. 8A, an etched sample is indicated by the unit area of an etched tunnel barrier layer. In the MTJ element, CoFeB was used as a recording layer, and an alloy containing a noble metal such as Pt and a magnetic material such as Ni or Co was used as a reference layer. In addition, MgO was used as a tunnel barrier layer.

A solid line A indicates the relationship between the applied magnetic flux density and magnetization of an unetched sample. A one-dot dashed line B indicates the relationship between the magnetic flux density and magnetization of a sample etched with gaseous Cl₂ and washed with pure water. A broken line C indicates the relationship between the magnetic flux density and magnetization of a sample etched with gaseous Cl₂ and processed by the steps of this embodiment.

As shown in FIG. 8A, the magnitude of the saturation magnetization saturates once as the magnetic flux density changes, and then rises (jumps). This jump of the saturation magnetization indicates that the magnetization direction in the recording layer matches that in the reference layer. The magnitude of the jump can be regarded as the magnitude of the magnetism-resistance change ratio when using the MTJ element as a magnetoresistive device. That is, the larger the jump, the better the magnetic characteristic of the MTJ element. In FIG. 8A, etching damage is estimated by comparing the jump amounts of the unetched and etched samples.

The jump amount of the saturation magnetization of the unetched sample is d0. This indicates the jump amount of an MTJ element having a favorable magnetic characteristic.

In contrast, the jump amount of the saturation magnetization of the sample etched with gaseous Cl₂ and washed with pure water is d1. Jump amount d1 was smaller by about 30% than jump amount d0 of the saturation magnetization of the unetched sample. This is so because Cl₂ used in the etching remained on the circumferential wall of the recording layer by adsorption and generated Cl ions when dissolved in water, and the Cl ions corroded CoFeB. If no pure water washing is performed, the corrosion continuously progresses, and the jump amount reduces more.

In contrast, the jump amount of the saturation magnetization of the sample etched with gaseous Cl₂ and processed by the steps of this embodiment is d2. Jump amount d2 is almost equal to jump amount d0 of the saturation amount of the unetched sample. That is, the sample processed by the steps of this embodiment presumably had almost no damage caused by the corrosion of the recording layer after the etching. This is probably because most Cl₂ was removed by active hydrogen, and the BN film 14 prevented the invasion of the water in the atmosphere.

### <Effects>

In the above-mentioned embodiment, after the multilayered structure as the MTJ element 10 is etched with gaseous Cl₂, the BN film 14 is formed on the side surfaces of the first fixed layer 4, the second fixed layer 8 and the free layer 6 (magnetic material). The BN film 14 prevents the invasion of the water (H ions) in the atmosphere. This makes it possible to prevent the reaction between the Cl₂ 12 remaining on the side surface of the magnetic material and Co or Fe forming the magnetic material. Accordingly, it is possible to prevent the damage layer 13 from being formed by the corrosion product such as CoCl₂ or FeCl₂ on the side surface of the magnetic material, and suppress the decrease in magnetic characteristic of the MTJ element.

The above-mentioned effect may be obtained by forming another insulating film (for example, an SiN film) on the side surface of the magnetic material, instead of the BN film 14. When using, for example, an SiN film, however, a source gas for forming the SiN film itself contains H ions. Accordingly, the reaction between residual Cl₂ and Co or Fe progresses and corrosion occurs.

Furthermore, the tolerance of the SiN film is lower than that of the BN film 14. Therefore, the source gas of the interlayer dielectric film (for example, an SiO₂ film) 15 to be formed later contains H ions, and the H ions invade through the SiN film and causes corrosion.

In contrast, the BN film 14 has a high tolerance and hence can avoid the above problem. In addition, since the BN film 14 is densely formed, it can prevent the invasion of H ions even when the film thickness is small. That is, the MTJ element 10 can be made smaller.

Also, in this embodiment, the hydrogen plasma (hydrogen radicals) is supplied after the multilayered structure is etched with gaseous Cl₂ and the BN film 14 is formed. This makes it possible to remove and reduce the Cl₂ 12 remaining on the surface. By thus removing and reducing the Cl₂ 12 that causes corrosion, therefore, it is possible to further suppress the decrease in magnetic characteristic of the MTJ element.

In addition, in this embodiment, the BN film 14 is formed in the same first plasma processing chamber 23 as that for the plasma etching of the multilayered structure. This is so because the formation of the BN film 14 and the plasma etching of the multilayered structure can be performed by using the same gas. That is, the throughput of manufacture can be increased because the etching step and deposition step are successively performed in the same chamber.

It is also possible to perform the etching step and deposition step not in the first plasma processing chamber 23 but in the second plasma processing chamber 25 having the same function as that of the first plasma processing chamber 23. That is, while the etching step is performed on a given wafer in one chamber, the deposition step can be performed on another wafer in the other chamber. This makes it possible to increase the throughput of manufacture.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetoresistive memory element comprising:
a multilayered structure on a substrate, the multilayered structure comprising:
a fixed layer comprising an invariable magnetization direction;
a free layer, the free layer comprising one of cobalt and iron, the free layer further comprising a variable magnetization direction; and
a nonmagnetic layer between the fixed layer and the free layer; and
an insulting film on a side surface of the free layer, the insulating film comprising boron and nitrogen.

2. The magnetoresistive memory element of claim 1, wherein the fixed layer comprises one of cobalt and iron and wherein the insulating film is on a side surface of the fixed layer.

3. The magnetoresistive memory element of claim 1, wherein the insulating film comprises one of a boron nitride (BN) film and a boron carbon nitride (BCN) film.

4. A method of manufacturing a magnetoresistive memory element, the method comprising:
forming a multilayered structure on a substrate, the multilayered structure comprising:
a fixed layer, the fixed layer comprising an invariable magnetization direction;
a free layer, the free layer comprising one of cobalt and iron, the free layer further comprising a variable magnetization direction; and
a nonmagnetic layer sandwiched between the fixed layer and the free layer;
forming a hard mask over the multilayered structure;
etching the multilayered structure with a gas containing chlorine, the hard mask used as a mask for the etching; and
forming an insulating film containing boron and nitrogen on a side surface of the etched free layer.

5. The method of claim 4, wherein forming the insulating film comprises supplying gaseous nitrogen and one of gaseous boron trichloride, gaseous boron trifluoride, and gaseous diborane.

6. The method of claim 5, wherein the gaseous nitrogen and the one of the gaseous boron trichloride, gaseous boron trifluoride, and gaseous diborane are formed into a plasma.

7. The method of claim 5, further comprising adding one of gaseous methane and gaseous carbon monoxide to the gaseous nitrogen and one of the gaseous boron trichloride, gaseous boron trifluoride, and gaseous diborane.

8. The method of claim 4, wherein the fixed layer comprises one of cobalt and iron and wherein the insulating film is on a side surface of the fixed layer.

9. The method of claim 4, further comprising removing chlorine adhering to the side surface of the free layer after etching the multilayered structure.

10. The method of claim 9, wherein the multilayered structure is etched in a first chamber, the insulating film is formed in the first chamber, and chlorine adhering to the side surface of the free layer is removed in a second chamber different from the first chamber, and wherein the substrate is transported in a vacuum between the first chamber and the second chamber.

11. The method of claim 9, wherein removing chlorine adhering to the side surface of the free layer comprises supplying one of gaseous hydrogen, gaseous nitrogen, and gaseous argon.

12. The method of claim 11, wherein the one of the gaseous hydrogen, gaseous nitrogen, and gaseous argon is formed into a plasma.

13. The method of claim 4, wherein the gas containing chlorine comprises one of gaseous chlorine, gaseous hydrogen chloride, and gaseous boron trichloride.

14. The method of claim 13, wherein the one of the gaseous chlorine, gaseous hydrogen chloride, and gaseous boron trichloride is formed into a plasma.

15. The method of claim 13, wherein one of an inert gas, an oxidizing gas, and a nitriding gas is added to the one of the gaseous chlorine, gaseous hydrogen chloride, and gaseous boron trichloride.

16. The method of claim 4, further comprising removing chlorine adhering to a side surface of the insulating film after forming the insulting film.

17. The method of claim 16, wherein
the multilayered structure is etched in a first chamber, the insulating film is formed in the first chamber, and the chlorine adhering to the side surface of the insulating film is removed in a second chamber different from the first chamber, and
the substrate is transported in a vacuum between the first chamber and the second chamber.

18. The method of claim 16, wherein the chlorine adhering to the side surface of the insulating film is removed by supplying one of gaseous hydrogen, gaseous nitrogen, and gaseous argon.

19. The method of claim 18, wherein the one of the gaseous hydrogen, gaseous nitrogen, and gaseous argon is formed into a plasma.
